(19) United States
(12) Patent Application Publication
(10) Pub. No.: US 2026/0039298 A1
(43) Pub. Date: Feb. 5, 2026

(54) SEMICONDUCTOR DEVICE

(71) Applicant: Renesas Electronics Corporation, Tokyo (JP)

(72) Inventors: Tetsuya TAKAHASHI, Tokyo (JP); Fukashi MORISHITA, Tokyo (JP)

(73) Assignee: Renesas Electronics Corporation, Tokyo (JP)

(21) Appl. No.: 19/283,756

(22) Filed: Jul. 29, 2025

(30) Foreign Application Priority Data
Jul. 30, 2024 (JP) 2024-123296

(51) Int. Cl. H03K 19/00; H03K 19/003

(52) U.S. Cl. CPC H03K 19/0013; H03K 19/0016; H03K 19/00384

(57) ABSTRACT

A semiconductor device configured to suppress increase in power consumption increased by temperature increase is provided. A logic circuit has characteristics in which a lower limit voltage achieving operations is decreased by temperature increase. A reference voltage generation circuit generates a reference voltage based on a negative coefficient voltage Vpn2 decreased by temperature increase. A voltage regulator circuit generates a power supply voltage based on the reference voltage. A power supply voltage maintenance circuit suppresses decrease in the reference voltage decreased by temperature increase, before the power supply voltage is made lower than a lower limit voltage by temperature increase.

### CROSS-REFERENCE TO RELATED APPLICATION

This application claims priority under 35 U.S.C. § 119 to Japanese Patent Application No. 2024-123296 filed on Jul. 30, 2024. The disclosure of Japanese Patent Application No. 2024-123296, including the specification, drawings and abstract is incorporated herein by reference in its entirety.

### BACKGROUND

The present invention relates to a semiconductor device, and relates to, for example, a semiconductor device including a logic circuit and a power supply circuit.

There is disclosed technique listed below.

[Non-Patent Document 1] T. Gyohten, F. Morishita, et al., “An On-chip PVT Control System for Worst-caseless Lower Voltage SoC Design,” A-SSCC Digest of Technical Paper, 2005

The Non-Patent Document 1 discloses an on-chip PVT (process, voltage, temperature) control system for an SoC having a low voltage specification. The control system detects an accurate temperature by using two oscillators different from each other in temperature characteristics, and determines a voltage level corresponding to the detected temperature, based on a registration content of a lookup table. In order to compensate for a process variation of the oscillator, the registration content of the lookup table is adjusted by previously checking a temperature detection result detected by the oscillator under use of an external tester.

### SUMMARY

In recent years, particularly, in an IC (integrated circuit) dedicated for small-scale equipment typified by a smartphone and a tablet, in other words, in a semiconductor device, reduction in the number of terminals, package downsizing and others have been required. However, the decrease in the number of terminals and the package downsizing generally decrease heat dissipation characteristics. As a result, in a thermal design of the semiconductor device, it is difficult to ensure a sufficient temperature margin considering self-heating and an ambient temperature. Particularly, power consumption, conclusively self-heating, in a semiconductor device including a logic circuit may be increased by temperature increase even in operation at certain power supply voltage and operation frequency. The further increase in the self-heating at the high temperature as described above causes a risk of further difficulty in the thermal design of the semiconductor device.

Embodiments described below have been made in consideration of such circumstances, and other problems and novel characteristics will be apparent from the description of the present specification and the accompanying drawings.

A semiconductor device according to one embodiment includes: a logic circuit; and a power supply circuit supplying a power supply voltage to the logic circuit. The logic circuit has characteristics in which a lower limit voltage achieving operations is decreased by temperature increase. The power supply circuit includes: a reference voltage generation circuit; a voltage regulator circuit; and a power supply voltage maintenance circuit. The reference voltage generation circuit generates a reference voltage based on a first voltage decreased by temperature increase. The voltage regulator circuit generates the power supply voltage based on the reference voltage. The power supply voltage maintenance circuit suppresses decrease in the reference voltage decreased by temperature increase, before the power supply voltage is made lower than the lower limit voltage by temperature increase.

According to the embodiment, in the semiconductor device, increase in the power consumption increased by temperature increase can be suppressed.

### BRIEF DESCRIPTIONS OF THE DRAWINGS

FIG. 1A is a block diagram illustrating a configuration example of a semiconductor device according to a first embodiment.

FIG. 1B is a schematic diagram illustrating an external shape example of the semiconductor device according to the first embodiment.

FIG. 2 is a circuit diagram illustrating a configuration example of a principal part of a power supply circuit illustrated in FIG. 1A.

FIG. 3 is a schematic diagram illustrating an operation example focused on a reference voltage generation circuit in the power supply circuit illustrated in FIG. 2.

FIG. 4 is a diagram illustrating a problem in a case without a power supply voltage maintenance circuit in the power supply circuit illustrated in FIG. 2.

FIG. 5 is a schematic diagram illustrating an operation example of the power supply circuit illustrated in FIG. 2.

FIG. 6 is a diagram illustrating an example of a relationship between a limit voltage illustrated in FIG. 2 and a channel length of a MOS transistor.

FIG. 7 is a diagram for explaining an example of a problem, which is different from that illustrated in FIG. 16, in a case of use of a power supply voltage independent of temperature.

FIG. 8 is a circuit diagram illustrating a configuration example of a principal part of a power supply circuit illustrated in FIG. 1A in a semiconductor device according to a second embodiment.

FIG. 9 is a circuit diagram illustrating a detailed configuration example of an amplifier circuit illustrated in FIG. 8.

FIG. 10 is a schematic diagram illustrating an operation example of the power supply circuit illustrated in FIG. 8.

FIG. 11 is a circuit diagram illustrating a configuration example of a principal part of the power supply circuit illustrated in FIG. 1A in a semiconductor device according to a third embodiment.

FIG. 12A is a schematic diagram for explaining an operation example related to a determination circuit illustrated in FIG. 11.

FIG. 12B is a schematic diagram for explaining an operation example related to the determination circuit illustrated in FIG. 11.

FIG. 13 is a schematic diagram illustrating an operation example of the power supply circuit illustrated in FIG. 11.

FIG. 14 is a circuit diagram illustrating a configuration example of a principal part of a power supply circuit in a semiconductor device according to a comparative example.

FIG. 15 is a diagram illustrating an example of respective temperature characteristics of a reference voltage and a power supply voltage illustrated in FIG. 14.

FIG. 16 is a diagram illustrating an example of temperature characteristics related to power consumption of a logic circuit in FIG. 14.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

In the embodiments described below, a p-channel MOSFET (metal oxide semiconductor field effect transistor) and an n-channel MOSFET are respectively referred to as a pMOS transistor and an nMOS transistor. Hereinafter, embodiments of the present invention will be described in detail with reference to the accompanying drawings. Note that the same components are denoted with the same reference symbols in principle throughout all the drawings for describing the embodiments, and the repetitive description thereof will be omitted.

### First Embodiment

### Configuration of Semiconductor Device

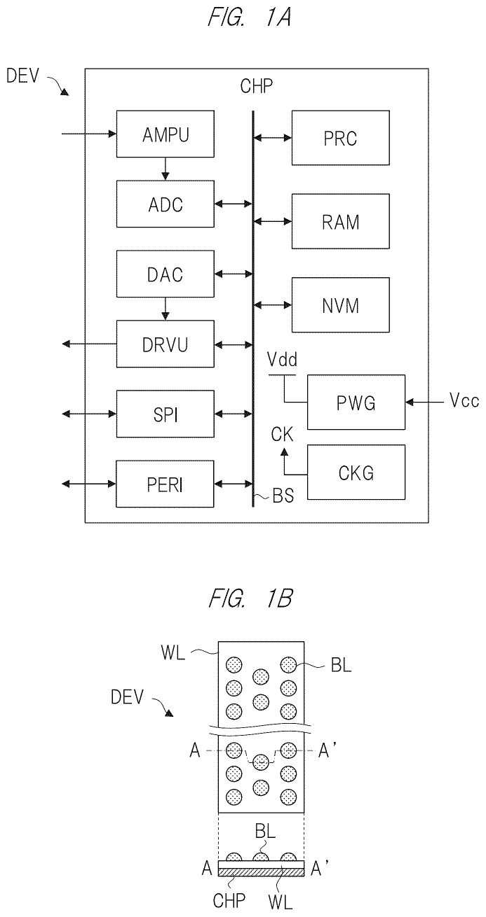

FIG. 1A is a block diagram illustrating a configuration example of a semiconductor device according to a first embodiment. FIG. 1B is a schematic diagram illustrating an external shape example of the semiconductor device according to the first embodiment. The semiconductor device DEV illustrated in FIG. 1A is, for example, an SoC (system on chip), a microcontroller or the like, including a semiconductor chip CHP.

The semiconductor device DEV includes a processor PRC, a volatile memory RAM, a non-volatile memory NVM, an analog-to-digital converter ADC, a digital-to-analog converter DAC, a serial-parallel interface SPI, various peripheral circuits PERI, a driver unit DRVU, and a bus BS that connects these components to one another. Further, the semiconductor device DEV includes an amplifier unit AMPU, a power supply circuit PWG, and a clock generation circuit CKG. These components are formed on the single semiconductor chip CHP.

As an example, the semiconductor device DEV controls an external system including a sensor, an actuator, and the like. In this case, the amplifier unit AMPU receives a detection signal, i.e., an analog signal, as its input from the sensor, and amplifies the input analog signal. The analog-to-digital converter ADC converts the signal amplified by the amplifier unit AMPU into a digital signal. The digital-to-analog converter DAC converts the digital signal, being input via the bus BS, into an analog signal. The driver unit DRVU drives the actuator, based on the analog signal transmitted from the digital-to-analog converter DAC. The driver unit DRVU may also drive the actuator by using a PWM (pulse width modulation) signal, based on the digital signal being input via the bus BS.

The serial parallel interface SPI performs predetermined digital communication with the external system by using serial/parallel conversion. The various peripheral circuits PERI supply other functions required to control the external system. The volatile memory RAM is, for example, a SRAM (static random access memory). The non-volatile memory NVM is, for example, a flash memory. The processors PRC includes a CPU (central processing unit), and may additionally include a DSP (digital signal processor), a GPU (graphics processing unit), or the like.

The processor PRC executes a predetermined program such as a control program for the external system, copied from the non-volatile memory NVM onto the volatile memory RAM. In this manner, the processor PRC receives, for example, as its input, the digital signal from the analog-to-digital converter ADC, conclusively the detection signal from the sensor via the bus BS, and generates an operation signal corresponding to the detection signal. The processor PRC outputs the generated operation signal via the bus BS, the digital-to-analog converter DAC, and the driver unit DRVU, to control the actuator.

The clock generation circuit CKG generates a reference clock signal based on an external crystal oscillator not illustrated, and generates a clock signal CK based on the reference clock signal by using a PLL (phase locked loop) circuit or the like. The clock generation circuit CKG supplies the generated clock signal CK to a logic circuit typified by the processor PRC.

Although described in detail later, the power supply circuit PWG generates various internal power supply voltages each having a predetermined voltage value, such as a power supply voltage Vdd for the logic circuit, by using an externally-supplied external power supply voltage Vcc. In the example illustrated in FIG. 1A, the logic circuit mainly corresponds to the processor PRC, and may additionally correspond to the volatile memory RAM, the serial parallel interface SPI, or the like.

The semiconductor device DEV illustrated in FIG. 1A may be made as, for example, a package as illustrated in FIG. 1B. FIG. 1B illustrates a planar configuration example of the semiconductor device DEV and a cross-sectional configuration example of a portion between A and A′. In FIG. 1B, solder balls BL as package terminals are formed above the semiconductor chip CHP via a wiring layer WL. The wiring layer WL connects an electrode pad of the semiconductor chip CHP and the solder balls BL to each other. The package is referred to as a CSP (chip size package), a WLP (wafer level package), a WLCSP (wafer level CSP), or the like.

Particularly for a semiconductor device DEV for small-scale equipment typified by a smartphone and a tablet, not a QFP (quad flat package) or the like but a small package having a small number of terminals, such as a CSP, may often be used. A specific example of the semiconductor device DEV illustrated in FIGS. 1A and 1B is an IC for an OIS (optical image stabilizer). In this case, the semiconductor device DEV is mounted on a small space around a small module including a camera lens.

Particularly, heat dissipation characteristics under use of the package such as the CSP may be lower than that under use of a package including a heat dissipation member such as a bonding wire or a lead frame. Further, the mounting space of the package may often be arranged in a portion making the heat dissipation characteristics difficult to be exhibited. Correspondingly, in the thermal design of the semiconductor device DEV, in other words, the package design thereof, it is difficult to ensure a sufficient temperature margin considering the self-heating and the ambient temperature. Therefore, in the embodiment, the temperature margin is enlarged by devisal for the power supply circuit PWG as described later.

### As to Power Supply Circuit (Comparative Example)

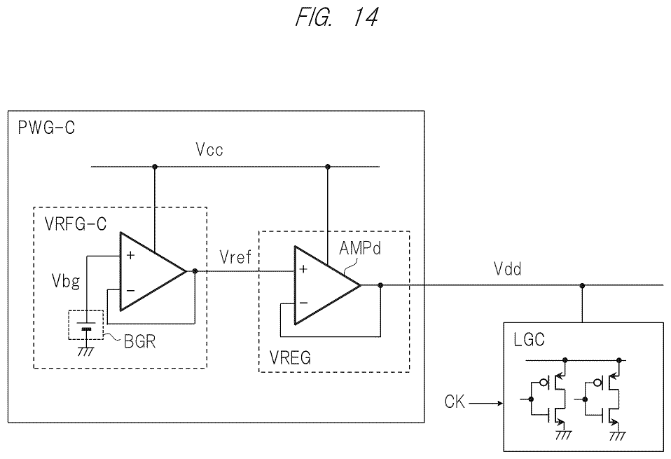

First, a power supply circuit as a comparative example will be described. FIG. 14 is a circuit diagram illustrating a configuration example of a principal part of a power supply circuit in a semiconductor device as a comparative example. As described in FIG. 1A, a power supply circuit PWG-C illustrated in FIG. 14 generates the power supply voltage Vdd for the logic circuit LGC typified by the processor PRC by using the externally-supplied external power supply voltage Vcc. As an example, the external power supply voltage Vcc and the power supply voltage Vdd are respectively about 3.3 V and about 1.2 V. The power supply circuit PWG-C includes a reference voltage generation circuit VRFG-C and a voltage regulator circuit VREG.

The reference voltage generation circuit VRFG-C includes a bandgap reference circuit BGR that generates a bandgap voltage Vbg. The reference voltage generation circuit VRFG-C generates a reference voltage Vref based on the bandgap voltage Vbg. The voltage regulator circuit VREG receives the reference voltage Vref as its input, and generates the power supply voltage Vdd by using an exclusive-to-drive amplifier circuit AMPd having a high driving performance. In this example, in an assumption that each of the bandgap voltage Vbg, the reference voltage Vref and the power supply voltage Vdd is about 1.2 V, the amplifier circuit AMPd configures a voltage follower circuit.

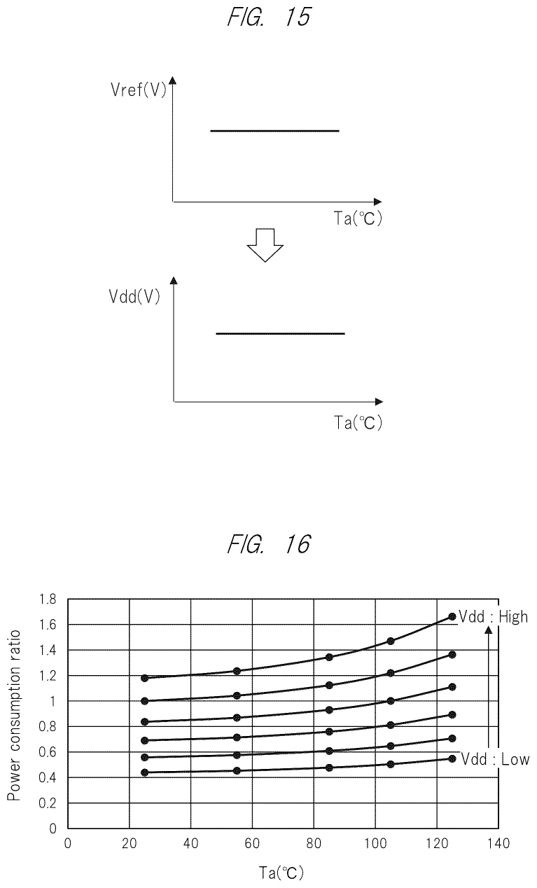

FIG. 15 is a diagram illustrating respective examples of temperature characteristics of the reference voltage Vref and the power supply voltage Vdd illustrated in FIG. 14. The bandgap voltage Vbg is a voltage having no temperature dependence. Accordingly, as illustrated in FIG. 15, the reference voltage Vref and the power supply voltage Vdd are also each a voltage having no temperature dependence.

FIG. 16 is a diagram illustrating an example of temperature characteristics related to power consumption of the logic circuit LGC in FIG. 14. In use of the power supply voltage Vdd, an operation frequency “fclk” of a clock signal CK, and a load capacitance “C_{L}” of the logic circuit LGC, the power consumption “Pw” of the logic circuit LGC is provided as “Pw=fclk*C_{L}*Vdd²”.

However, even if both the power supply voltage Vdd and the operation frequency “fclk” are constant, the power consumption of the logic circuit LGC is generally exponentially increased by the temperature increase as illustrated in FIG. 16. This is mainly because the temperature increase decreases a threshold voltage of a MOS transistor configuring the logic circuit LGC, conclusively increases an on-state current. Further, the higher the power supply voltage Vdd is, the more the increase in the power consumption of the logic circuit LGC is.

Thus, the more the increase in the power consumption, conclusively the self-heating, is due to the temperature increase, in other words, due to increase in a peripheral temperature Ta, the higher a junction temperature (Tj) is. As a result, in the thermal design of the semiconductor device DEV, in other words, the package design thereof, it may be difficult to ensure the sufficient temperature margin. Such a problem is more noticeable when, for example, the small-scale package is mounted on the small space as described in FIG. 1B. Therefore, it is beneficial to use a power supply circuit according to the following embodiment.

### Configuration of Power Supply Circuit (First Embodiment)

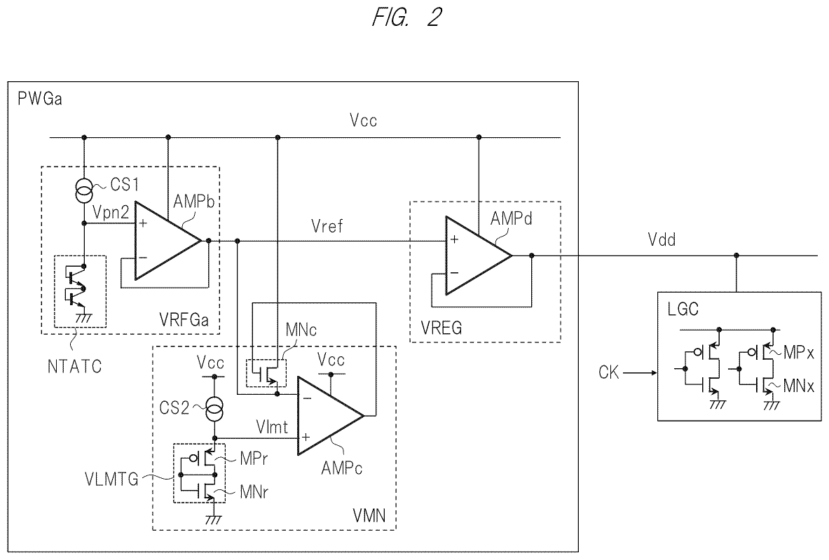

FIG. 2 is a circuit diagram illustrating a configuration example of a principal part of the power supply circuit PWG illustrated in FIG. 1A. A power supply circuit PWGa illustrated in FIG. 2 generates the power supply voltage Vdd for the logic circuit LGC typified by the processor PRC by using the external power supply voltage Vcc supplied from outside. The power supply circuit PWGa supplies the generated power supply voltage Vdd to the logic circuit LGC. The logic circuit LGC operates based on the power supply voltage Vdd and the clock signal CK from the clock generation circuit CKG.

The logic circuit LGC includes a CMOS inverter circuit made of a pMOS transistor MPx and an nMOS transistor MNx and the like. The respective magnitudes of threshold voltages of the pMOS transistor MPx and the nMOS transistor MNx are decreased by the temperature increase. Accordingly, the logic circuit LGC has characteristics in which a lower limit voltage achieving operations is decreased by the temperature increase. Correspondingly, as described in FIG. 16, the logic circuit LGC also has characteristics in which the power consumption at the constant power supply voltage Vdd is increased by the temperature increase.

The power supply circuit PWGa includes a reference voltage generation circuit VRFGa, a power supply voltage maintenance circuit VMN, and a voltage regulator circuit VREG. The reference voltage generation circuit VRFGa generates a reference voltage Vref based on a voltage decreased by the temperature increase, in other words, based on a voltage having a negative temperature coefficient. Specifically, the reference voltage generation circuit VRFGa includes, for example, an NTAT (negative to absolute temperature) circuit “NTATC”, a constant current source CS1, and an exclusive-to-buffer amplifier circuit AMPb.

The constant current source CSI causes a constant current to flow through the NTAT circuit NTATC. Correspondingly, the NTAT circuit NTATC generates a negative coefficient voltage (first voltage) Vpn2 having a negative temperature coefficient. The exclusive-to-buffer amplifier circuit AMPb configures, for example, a voltage follower circuit. The amplifier circuit AMPb receives the negative coefficient voltage Vpn2 as its positive-electrode input from the NTAT circuit NTATC, and outputs the reference voltage Vref based on the negative coefficient voltage Vpn2, in other words, following the negative coefficient voltage Vpn2.

In this example, the NTAT circuit NTATC is achieved by extracting a base-emitter voltage “V_{BE}” generated when a constant current is caused to flow through a diode-connected bipolar transistor. However, the NTAT circuit NTATC may be achieved by a system of extracting a gate-source voltage “V_{GS}” of a diode-connected MOS transistor to be used instead of the diode-connected bipolar transistor.

The voltage regulator circuit VREG operates at an external power supply voltage Vcc of, for example, about 3.3 V, and generates the power supply voltage Vdd based on the reference voltage Vref output from the reference voltage generation circuit VRFGa. In this example, in an assumption that both the reference voltage Vref and the power supply voltage Vdd are each about 1.2 V, the voltage regulator circuit VREG is made of the voltage follower circuit using the exclusive-to-drive amplifier circuit AMPd having the high driving performance. However, the voltage regulator circuit VREG may be made of, for example, an LDO (low drop out) regulator or the like, depending on a specification of the power supply voltage Vdd.

Before the power supply voltage Vdd of the logic circuit LGC is made lower than the above-described lower limit voltage by the temperature increase, the power supply voltage maintenance circuit VMN suppresses the decrease in the reference voltage Vref, conclusively the power supply voltage Vdd, caused by the temperature increase. The power supply voltage maintenance circuit VMN suppresses the decrease in the reference voltage Vref caused by the temperature increase, by using a limit voltage Vlmt having a negative temperature coefficient. Specifically, the power supply voltage maintenance circuit VMN includes a limit voltage generation circuit VLMTG that generates the limit voltage Vlmt, a constant current source CS2, an exclusive-to-clamp amplifier circuit AMPc, and an exclusive-to-clamp nMOS transistor MNc.

The limit voltage generation circuit VLMTG includes a pMOS transistor MPr and an nMOS transistor MNr connected in series with the pMOS transistor MPr. The pMOS transistor (first transistor) MPr has a diode connection and is formed by the same manufacturing process as that of the pMOS transistor MPx used for the logic circuit LGC. Similarly, the nMOS transistor (second transistor) MNr has a diode connection and is formed by the same manufacturing process as that of the nMOS transistor MNx used for the logic circuit LGC.

The constant current source CS2 causes a constant current to flow through the limit voltage generation circuit VLMTG. As a result, a threshold voltage “Vthp” on which a variation in manufacture of the pMOS transistor MPx in the logic circuit LGC is reflected is generated between the source and the drain of the pMOS transistor MPr. Similarly, a threshold voltage “Vthn” on which a variation in manufacture of the nMOS transistor MNx in the logic circuit LGC is reflected is generated between the source and the drain of the nMOS transistor MNr. The limit voltage Vlmt is a sum voltage of the threshold voltage “Vthp” and the threshold voltage “Vthn”.

More specifically, the channel length of the pMOS transistor MPr is larger than the channel length of the pMOS transistor MPx in the logic circuit LGC. Similarly, the channel length of the nMOS transistor MNr is larger than the channel length of the nMOS transistor MNx in the logic circuit LGC. This allows the limit voltage Vlmt to have a certain margin, although described in detail later.

The amplifier circuit AMPc receives the limit voltage Vlmt and the reference voltage Vref, respectively, as its positive electrode input and its negative electrode input, and controls a gate voltage of the exclusive-to-clamp nMOS transistor MNc. The external power supply voltage Vcc is applied to the drain of the nMOS transistor MNc. The source of the nMOS transistor MNc is connected to the negative electrode input of the amplifier circuit AMPc, conclusively to a node of the reference voltage Vref.

The amplifier circuit AMPc compares the limit voltage Vlmt and the reference voltage Vref, conclusively the negative coefficient voltage (first voltage) Vpn2. Then, when the reference voltage Vref is not lower than the limit voltage Vlmt, the amplifier circuit AMPc controls the nMOS transistor MNc to be off. As a result, the magnitude of the reference voltage Vref is determined based on the negative coefficient voltage Vpn2.

On the other hand, when the reference voltage Vref is lower than the limit voltage Vlmt, the amplifier circuit AMPc controls the nMOS transistor MNc to be on. As a result, the negative electrode input of the amplifier circuit AMPc is controlled through the nMOS transistor MNc to have the limit voltage Vlmt. That is, the amplifier circuit AMPc is stabilized to output a voltage that is higher by the threshold voltage magnitude of the nMOS transistor MNc than the limit voltage Vlmt. As a result, the magnitude of the reference voltage Vref is determined based on the limit voltage Vlmt.

Thus, the power supply voltage maintenance circuit VMN compares the limit voltage Vlmt and the reference voltage Vref, conclusively the negative coefficient voltage (first voltage) Vpn2, and determines the magnitude of the reference voltage Vref based on either one of the voltages, whichever is higher. In the example illustrated in FIG. 2, the reference voltage generation circuit VRFGa still operates even in a period during which the exclusive-to-clamp nMOS transistor MNc is controlled to be on. In this case, in order to reduce dependence of the reference voltage Vref on the negative coefficient voltage Vpn2, for example, a driving performance on a sink side of the amplifier circuit AMPb is set sufficiently lower than a driving performance of the nMOS transistor MNc.

### Operation of Power Supply Circuit (First Embodiment)

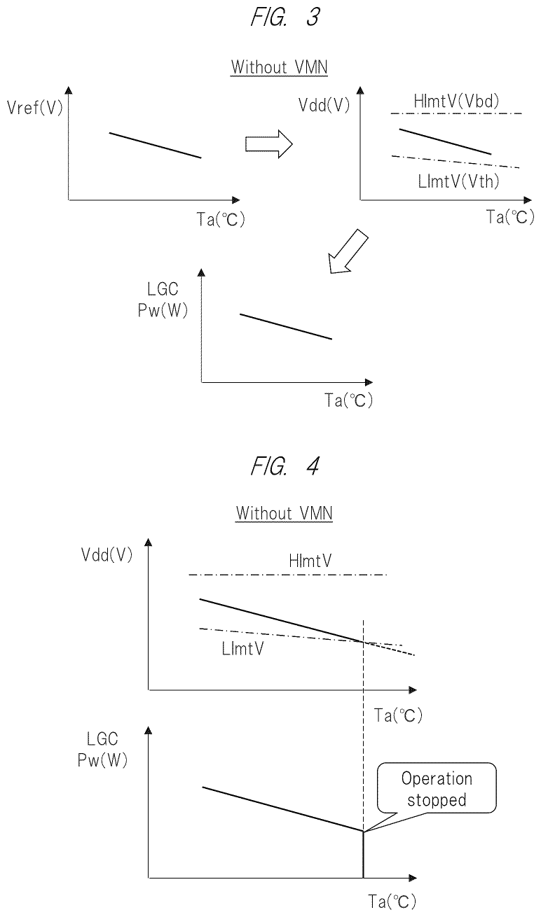

FIG. 3 is a schematic diagram illustrating an operation example focused on the reference voltage generation circuit VRFGa in the power supply circuit PWGa illustrated in FIG. 2. Here, a case without the power supply voltage maintenance circuit VMN is assumed. The reference voltage Vref has the negative temperature coefficient based on the negative coefficient voltage (first voltage) Vpn2. Correspondingly, the power supply voltage Vdd also has the negative temperature coefficient. Therefore, in the logic circuit LGC, the increase in the power consumption Pw caused by the temperature increase can be suppressed.

As a result, the self-heating can be decreased by the increase in the ambient temperature Ta, and therefore, the increase in the junction temperature (Tj) caused by the increase in the ambient temperature Ta can be suppressed. As a result, the sufficient temperature margin can be easily ensured in the thermal design of the semiconductor device DEV, in other words, the package design thereof. For example, even when the small-scale package as illustrated in FIG. 1B is used, the sufficient temperature margin can be ensured.

As illustrated in FIG. 3, an upper limit voltage HlmtV and a lower limit voltage LlmtV are determined for the power supply voltage Vdd. The upper limit voltage HlmtV is determined based on a breakdown voltage Vbd of the pMOS transistor MPx and the nMOS transistor MNx in the logic circuit LGC. On the other hand, the lower limit voltage LlmtV is determined based on a threshold voltage Vth of the pMOS transistor MPx and the nMOS transistor MNx in the logic circuit LGC. Accordingly, the lower limit voltage LlmtV is decreased by the temperature increase.

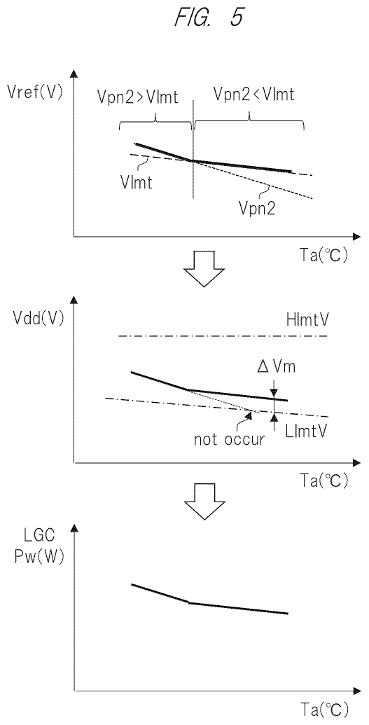

FIG. 4 is a diagram illustrating a problem in the case without the power supply voltage maintenance circuit VMN in the power supply circuit PWGa illustrated in FIG. 2. As illustrated in FIG. 4, a gradient of the lower limit voltage LlmtV with respect to the temperature is gentler than a gradient of the reference voltage Vref, conclusively a gradient of the power supply voltage Vdd with respect to the temperature. In other words, the gradient of the power supply voltage Vdd with respect to the temperature is steeper than the gradient of the lower limit voltage LlmtV with respect to the temperature. As a result, the power supply voltage Vdd may be lower than the lower limit voltage LlmtV when the temperature increases to some extent. In this case, the logic circuit LGC may stop operating. Therefore, the power supply voltage maintenance circuit VMN is provided.

FIG. 5 is a schematic diagram illustrating an operation example of the power supply circuit PWGa illustrated in FIG. 2. As illustrated in FIG. 5, a gradient of the limit voltage LlmtV with respect to the temperature is gentler than a gradient of the negative coefficient voltage (first voltage) Vpn2 with respect to the temperature. At a low temperature, when the negative coefficient voltage Vpn2 is higher than the limit voltage Vlmt, the reference voltage Vref is determined based on the negative coefficient voltage Vpn2. On the other hand, when the negative coefficient voltage Vpn2 is made lower than the limit voltage Vlmt by the temperature increase, the reference voltage Vref is limited to the limit voltage Vlmt.

A power supply voltage Vdd is generated based on the reference voltage Vref, in other words, to follow the reference voltage Vref. When the limit voltage generation circuit VLMTG as described in FIG. 2 is used, the gradient of the limit voltage Vlmt, conclusively the gradient of the power supply voltage Vdd based on the limit voltage Vlmt with respect to the temperature is equivalent to the gradient of the lower limit voltage LlmtV with respect to the temperature. The problem as described in FIG. 4 that the power supply voltage Vdd is made lower than the lower limit voltage LlmtV by the temperature increase can be prevented. As a result, in the logic circuit LGC, the normal operation can be ensured within the desired temperature range while the increase in the power consumption Pw caused by the temperature increase is suppressed.

As illustrated in FIG. 5, the power supply voltage Vdd based on the limit voltage Vlmt has the ensured voltage margin AVm with respect to the lower limit voltage LlmtV. As a result, a state where the power supply voltage Vdd is higher than the lower limit voltage LlmtV can be reliably maintained even in occurrence of, for example, a certain manufacturing variation or a temperature distribution in the semiconductor chip CHP. As one of methods for ensuring the voltage margin AVm, the channel length of the MOS transistor in the limit voltage generation circuit VLMTG is set larger than that in the logic circuit LGC, as described in FIG. 2.

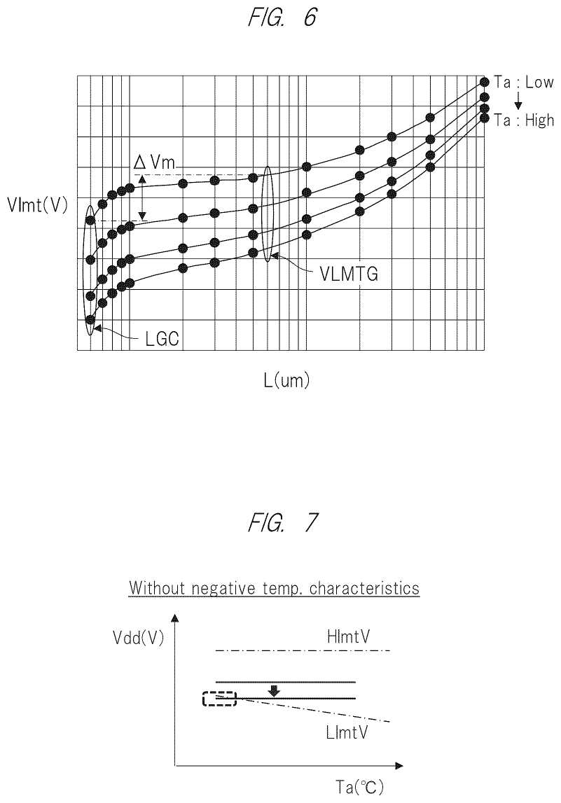

FIG. 6 is a diagram illustrating an example of a relationship between the limit voltage Vlmt illustrated in FIG. 2 and the channel length of the MOS transistor. The larger a channel length L is, the higher the threshold voltage of the MOS transistor is. Accordingly, as illustrated in FIG. 6, the larger the channel length L of the pMOS transistor MPr and the nMOS transistor MNr in the limit voltage generation circuit VLMTG becomes, the higher the limit voltage Vlmt also is. FIG. 6 illustrates an example of a state where the channel length L of the MOS transistor in the limit voltage generation circuit VLMTG is larger than that in the logic circuit LGC by one order of magnitude. As a result, a voltage margin AVm illustrated in FIG. 6 can be ensured.

### As to Various Supplementary Items

FIG. 7 is a diagram illustrating an example of a problem which is different from that illustrated in FIG. 16, in a case of use of a power supply voltage independent of the temperature. For example, under use of a reference voltage Vref having no temperature dependence, conclusively use of a power supply voltage Vdd, if a voltage value itself is set lower than normal, the power consumption, conclusively the heat generation can be suppressed. However, in this case, as illustrated in FIG. 7, at a low temperature, the power supply voltage Vdd may be lower than the lower limit voltage LlmtV. Accordingly, it is beneficial to make the reference voltage Vref have the negative temperature coefficient as similar to the system according to the embodiment.

Also, for example, a system for always determining the magnitude of the reference voltage Vref based on the limit voltage Vlmt without use of the negative coefficient voltage Vpn2 is also considered in FIG. 5. However, in this case, for example, at a low temperature, an operation speed of the logic circuit LGC may be excessively decreased by the low supply voltage Vdd, and a speed margin may be decreased. Thus, in consideration of a balance between the power consumption and the speed performance, the system using both the negative coefficient voltage Vpn2 and the limit voltage Vlmt as illustrated in FIG. 6 is beneficial.

Note that the power supply circuit PWG may be only a component that achieves the operation as illustrated in FIG. 5, and its configuration is not limited to the configuration example illustrated in FIG. 2, and various configurations are applicable. For example, the configuration of the power supply voltage maintenance circuit VMN may individually include a comparison circuit that compares the negative coefficient voltage Vpn2 and the limit voltage Vlmt and a selection circuit that determines one of the two voltages as the reference voltage Vref in accordance with the comparison result. However, from a viewpoint of a circuit area or the like, the configuration illustrated in FIG. 2 is beneficial. That is, the power supply voltage maintenance circuit VMN illustrated in FIG. 2 substantially has both a function of the comparison circuit and a function of the selection circuit.

### Main Effects of First Embodiment

As the power supply circuit that supplies the power supply voltage to the logic circuit, the semiconductor device according to the first embodiment includes: the reference voltage generation circuit that generates the reference voltage having the negative temperature coefficient; and the power supply voltage maintenance circuit that suppresses the decrease in the reference voltage caused by the temperature increase before the power supply voltage is made lower than the lower limit voltage by the temperature increase. As a result, in the semiconductor device including the logic circuit, the increase in the power consumption caused by the temperature increase can be suppressed. Further, the normal operation of the logic circuit can be ensured within the desired temperature range while the increase in the power consumption is suppressed. As a result, in the thermal design of the semiconductor device, in other words, the package design thereof, the desired temperature margin can be easily ensured, and the package design can be facilitated.

### Second Embodiment

### Configuration of Power Supply Circuit

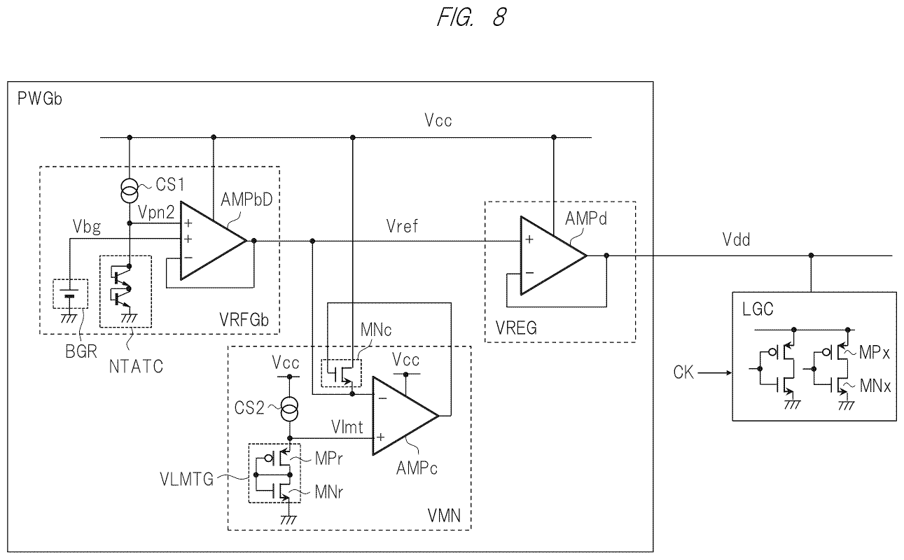

In the above-described first embodiment, the power supply circuit has performed control using the power supply voltage maintenance circuit VMN before the power supply voltage Vdd is made lower than the lower limit voltage LlmtV by the temperature increase. In a second embodiment, additionally, the power supply circuit also performs similar control before the power supply voltage Vdd is made higher than an upper limit voltage HlmtV by the temperature decrease. FIG. 8 is a circuit diagram illustrating a configuration example of a principal part of the power supply circuit PWG illustrated in FIG. 1A in the semiconductor device according to the second embodiment.

A power supply circuit PWGb illustrated in FIG. 8 differs from that illustrated in FIG. 2 in a configuration of a reference voltage generation circuit VRFGb. The reference voltage generation circuit VRFGb includes an exclusive-to-buffer amplifier circuit AMPbD that is different from that illustrated in FIG. 2. Further, the reference voltage generation circuit VRFGb includes a bandgap reference circuit BGR in addition to the NTAT circuit NTATC and the constant current source CSI that are similar to those illustrated in FIG. 2.

The bandgap reference circuit BGR generates a bandgap voltage Vbg having no temperature dependence. The amplifier circuit AMPbD is made of a voltage follower circuit having two positive electrode inputs. To the two positive electrode inputs, a negative coefficient voltage (first voltage) Vpn2 output from the NTAT circuit NTATC and the bandgap voltage (second voltage) Vbg output from the bandgap reference circuit BGR are respectively inputted. The amplifier circuit AMPbD operates based on the negative coefficient voltage Vpn2 or the bandgap voltage Vbg, whichever is lower.

That is, as substantial operations, the amplifier circuit AMPbD compares the negative coefficient voltage (first voltage) Vpn2 and the bandgap voltage (second voltage) Vbg, and determines the magnitude of the reference voltage Vref based on either one the voltages, whichever is lower. As a result, the reference voltage generation circuit VRFGb also has a function of a second power supply voltage maintenance circuit in addition to the function of the reference voltage generation circuit VRFGa as similar to the first embodiment. The second power supply voltage maintenance circuit suppresses the increase in the reference voltage Vref caused by the temperature decrease, before the power supply voltage Vdd is made higher than the upper limit voltage HlmtV of the logic circuit LGC by the temperature decrease.

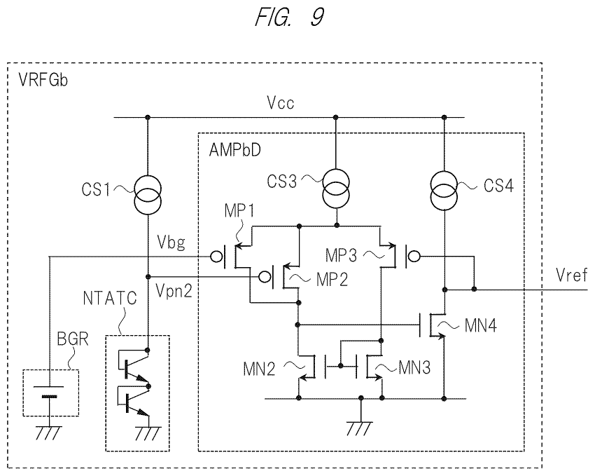

FIG. 9 is a circuit diagram illustrating a detailed configuration example of the amplifier circuit AMPbD illustrated in FIG. 8. The amplifier circuit AMPbD illustrated in FIG. 9 includes pMOS transistors MP1 to MP3, nMOS transistors MN2 to MN4, and constant current sources CS3 and CS4. The pMOS transistors MP1 to MP3, the nMOS transistors MN2 and MN3, and the constant current source CS3 configure a p-channel differential amplifier circuit. The nMOS transistor MN4 and the constant current source CS4 configure a source-grounded amplifier circuit in a stage succeeding the differential amplifier circuit.

In the differential amplifier circuit, the pMOS transistor MP1 and the pMOS transistor MP2 are connected in parallel between the common source and drain, and have gates that receive the bandgap voltage Vbg and the negative coefficient voltage Vpn2 as their inputs, respectively. Both the pMOS transistors MP1 and MP2 each plays a role of a positive electrode input of the differential amplifier circuit. The pMOS transistor MP3 plays a role of a negative electrode input of the differential amplifier circuit. The nMOS transistors MN2 and MN3 configure a current mirror circuit, and each plays a role of a load current source of the differential amplifier circuit. The constant current source CS3 plays a role of a tail current source of the differential amplifier circuit.

In the source-grounded amplifier circuit, the gate of the nMOS transistor MN4 receives a negative electrode output of the differential amplifier circuit, in other words, receives a common drain voltage of the pMOS transistors MP1 and MP2 as its input. The constant current source CS4 plays a role of a load current source of the source-grounded amplifier circuit. In response to the negative electrode output of the differential amplifier circuit, the nMOS transistor MN4 outputs the reference voltage Vref as its positive electrode output of the amplifier circuit AMPbD from its drain. Further, the nMOS transistor MN4 preforms negative feedback of this positive electrode output to the negative electrode input of the differential amplifier circuit, in other words, to the gate of the pMOS transistors MP3.

In such a configuration, the differential amplifier circuit mainly operates either one of the pMOS transistors MP1 and MP2, whichever is lower in the on resistance. Accordingly, the amplifier circuit AMPbD operates based on either one of the negative coefficient voltage Vpn2 and the bandgap voltage Vbg, whichever is lower. Note that the amplifier circuit AMPb illustrated in FIG. 2 may be achieved by, for example, a configuration of the amplifier circuit AMPbD illustrated in FIG. 9 excluding the pMOS transistor MP1.

As described in the first embodiment, the driving performance on the sink side of the amplifier circuit AMPbD may be set low such that the power supply voltage maintenance circuit VMN sets the reference voltage Vref to the limit voltage Vlmt. An exemplified specific example is a method of setting a gate width of the nMOS transistor MN4 illustrated in FIG. 9 to be sufficiently smaller than a gate width of an exclusive-to-clamp nMOS transistor MNc illustrated in FIG. 8. Alternatively, a resistive element or the like may be connected to the drain of the nMOS transistor MN4.

### Operation of Power Supply Circuit

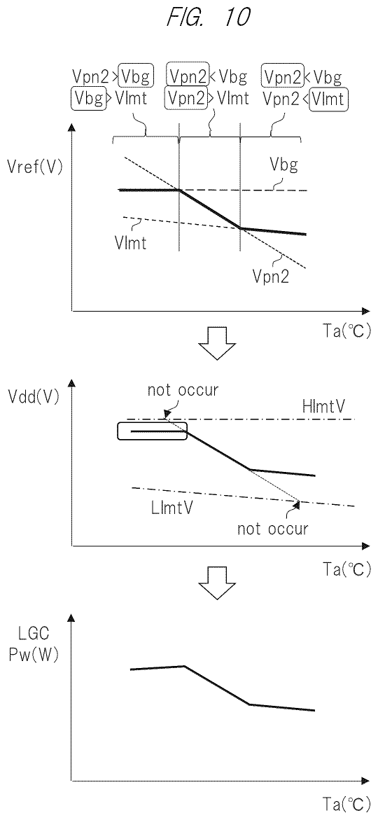

FIG. 10 is a schematic diagram illustrating an operation example of the power supply circuit PWGb illustrated in FIG. 8. As described above, the reference voltage generation circuit VRFGb compares the negative coefficient voltage Vpn2 and the bandgap voltage Vbg, and outputs either one of the voltages, whichever is lower, as the reference voltage Vref. On the other hand, the power supply voltage maintenance circuit VMN compares the limit voltage Vlmt and the reference voltage Vref output from the reference voltage generation circuit VRFGb, in other words, the negative coefficient voltage Vpn2 or the bandgap voltage Vbg, and determines either one of the voltages, whichever is higher, as the reference voltage Vref.

Accordingly, as illustrated in FIG. 10, at a low temperature, the reference voltage generation circuit VRFGb outputs the bandgap voltage Vbg, and the power supply voltage maintenance circuit VMN determines the reference voltage Vref to have the magnitude of the bandgap voltage Vbg. At a medium temperature, the reference voltage generation circuit VRFGb outputs the negative coefficient voltage Vpn2, and the power supply voltage maintenance circuit VMN determines the reference voltage Vref to have the magnitude of the negative coefficient voltage Vpn2. At a high temperature, the reference voltage generation circuit VRFGb outputs the negative coefficient voltage Vpn2, and the power supply voltage maintenance circuit VMN determines the reference voltage Vref to have the magnitude of the limit voltage Vlmt.

The power supply voltage Vdd is generated based on the reference voltage Vref, in other words, to follow the reference voltage Vref. As a result, as similar to the case illustrated in FIG. 5, the power supply voltage Vdd is not lower than the lower limit voltage LlmtV. In addition, as illustrated in FIG. 10, the power supply voltage Vdd is not higher than the upper limit voltage HlmtV. And, the magnitude of the power consumption Pw of the logic circuit LGC depends on the power supply voltage Vdd. However, more strictly, there may be influence of a variation in a threshold voltage. For example, if the power supply voltage Vdd is constant at a low temperature, the power consumption Pw may be slightly increased by the temperature increase as illustrated in FIG. 16.

### As to Supplementary Items

As similar to the case of the first embodiment, the configuration of the power supply circuit PWG may be only a component that achieves the operation as illustrated in FIG. 10, and is not limited to the configuration example illustrated in FIG. 8, and various configurations may be applicable. For example, the reference voltage generation circuit VRFGb, in other words, the second power supply voltage maintenance circuit may individually include a comparison circuit that compares the negative coefficient voltage Vpn2 and the bandgap voltage Vpg and a selection circuit that determines either one of the two voltages as the reference voltage Vref in accordance with the comparison result. However, from a viewpoint of a circuit area or the like, the configuration illustrated in FIG. 8 is beneficial. That is, the second power supply voltage maintenance circuit illustrated in FIG. 8 substantially has both a function of the comparison circuit and a function of the selection circuit.

### Main Effects of Second Embodiment

The use of the semiconductor device according to the second embodiment as described above provides the similar effects to the various effects described in the first embodiment. In addition to this, the situation where the power supply voltage is higher than the upper limit voltage at a low temperature can be prevented, thereby protecting a semiconductor chip or the like. Further, since the increase in the power supply voltage is suppressed at a low temperature, the increase in the power consumption at a low temperature can be also suppressed.

### Third Embodiment

### Configuration of Power Supply Circuit

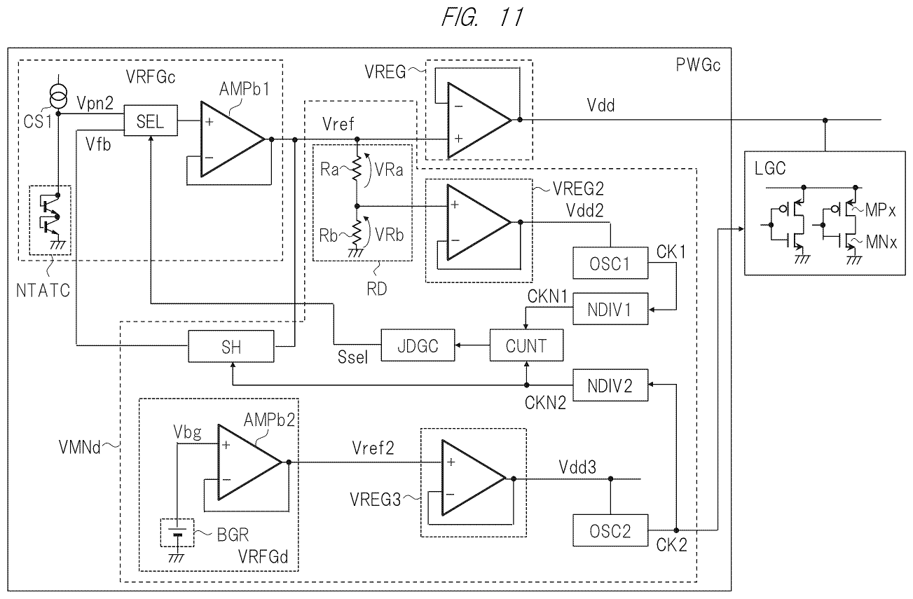

FIG. 11 is a circuit diagram illustrating a configuration example of a principal part of the power supply circuit PWG illustrated in FIG. 1A in a semiconductor device according to a third embodiment. A power supply circuit PWGc illustrated in FIG. 11 differs from that in the configuration example illustrated in FIG. 2 in the following two points. The first difference is that a power supply voltage maintenance circuit VMNd is made of a digital circuit if needed. The second difference is that a selection circuit SEL is additionally included in a reference voltage generation circuit VRFGc. Note that the selection circuit SEL is substantially a part of the power supply voltage maintenance circuit VMNd.

The power supply voltage maintenance circuit VMNd includes a resistive voltage division circuit RD, voltage regulator circuits VREG2 and VREG3, oscillators OSC1 and OSC2, frequency dividers NDIV1 and NDIV2, a counter circuit [symbol] , a determination circuit JDGC, a sample hold circuit SH, and a reference voltage generation circuit VRFGd. The resistive voltage division circuit RD resistively divides the reference voltage Vref by using resistive elements Ra and Rb.

The voltage regulator circuit (second voltage regulator circuit) VREG2 generates a power supply voltage Vdd2 based on the voltage divided by the resistive voltage division circuit RD. As a result, the voltage regulator circuit VREG2 generates the power supply voltage (second power supply voltage) Vdd2 being lower than the power supply voltage Vdd of a logic circuit LGC and having a negative temperature coefficient. The power supply voltage Vdd2 plays a similar role to that of the limit voltage Vlmt illustrated in FIG. 2.

The oscillator (first oscillator) OSC1 plays a similar role to that of the limit voltage generation circuit VLMTG illustrated in FIG. 2. The oscillator OSC1 is made of, for example, a ring oscillator circuit or the like including a MOS transistor formed by the same manufacturing process as that of the MOS transistor in the logic circuit LGC. As a result, the oscillator OSC1 has characteristics on which the variation in manufacture of the logic circuit LGC is reflected. The oscillator OSC1 oscillates at a frequency corresponding to the power supply voltage Vdd2. The frequency divider NDIV1 frequency-divides a clock signal CK1 output from the oscillator OSC1, and outputs a frequency-divided clock signal CKN1.

Meanwhile, the reference voltage generation circuit (second reference voltage generation circuit) VRFGd includes a bandgap reference circuit BGR and an exclusive-to-buffer amplifier circuit AMPb2 configuring a voltage follower circuit. The reference voltage generation circuit VRFGd generates another reference voltage Vref2 based on a bandgap voltage (second voltage) Vbg having no temperature dependence output from the bandgap reference circuit BGR. The voltage regulator circuit (third voltage regulator circuit) VREG3 generates a power supply voltage (third power supply voltage) Vdd3 based on the reference voltage Vref2.

The oscillator (second oscillator) OSC2 is made of, for example, a circuit including a MOS transistor formed by the same manufacturing process as that of the MOS transistor in the logic circuit LGC. The oscillator OSC2 oscillates at a fixed frequency corresponding to a constant power supply voltage Vdd3. The frequency divider NDIV2 frequency-divides a clock signal CK2 output from the oscillator OSC2, and outputs a frequency-divided clock signal CKN2. In this example, the clock signal CK2 output from the oscillator OSC2 is supplied to the logic circuit LGC. That is, the reference voltage generation circuit VRFGd, the voltage regulator circuit VREG3, and the oscillator OSC2 may be each a part of the clock generation circuit CKG illustrated in FIG. 1A.

The counter circuit [symbol] counts the number of clocks of the frequency-divided clock signal CKN1 having the variable frequency with respect to the frequency-divided clock signal CKN2 having the fixed frequency. That is, the counter circuit [symbol] functions as a frequency detection circuit that detects a frequency of the oscillator OSC1 with respect to the fixed frequency of the oscillator OSC2. The determination circuit JDGC determines whether or not the frequency of the oscillator OSC1 detected by the counter circuit [symbol] , in other words, by the frequency detection circuit is lower than a predetermined threshold frequency. Then, the determination circuit JDGC outputs a determination result as a selection signal Ssel.

The sample hold circuit SH sequentially holds the reference voltage Vref output from the reference voltage generation circuit VRFGc, in synchronization with the frequency-divided clock signal CKN2. The reference voltage generation circuit VRFGc is provided with the selection circuit SEL as described above. The selection circuit SEL selects one of a negative coefficient voltage Vpn2 output from the NTAT circuit NTATC and a feedback voltage Vfb held by the sample hold circuit SH, based on the selection signal Ssel. Then, the selection circuit SEL outputs the selected voltage to the positive electrode input of the exclusive-to-buffer amplifier circuit AMPb1 as similar to the case illustrated in FIG. 2.

In this manner, the power supply voltage maintenance circuit VMNd, more specifically the determination circuit JDGC, determines, based on the frequency of the oscillator OSC1, whether or not it is necessary to suppress the decrease in the reference voltage Vref, conclusively whether or not the power supply voltage Vdd is immediately before being lower than the lower limit voltage LlmtV of the logic circuit LGC. Then, if it is necessary to suppress the decrease in the reference voltage Vref, the power supply voltage maintenance circuit VMNd suppress the decrease in the reference voltage Vref caused by the temperature increase by repeatedly using the reference voltage Vref, in other words, the feedback voltage Vfb held in the sample hold circuit SH. That is, in this case, the determination circuit JDGC causes the selection circuit SEL to select the feedback voltage Vfb by using the selection signal Ssel.

### Operation of Power Supply Circuit

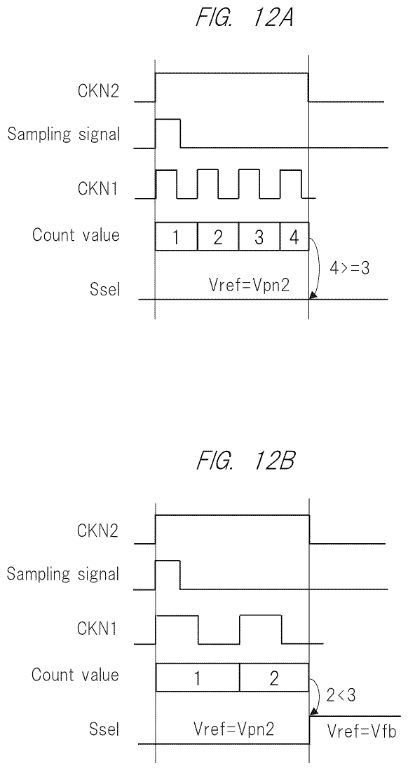

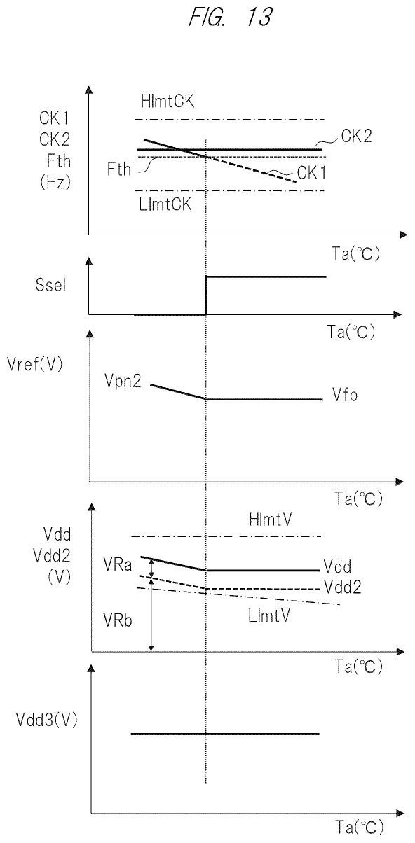

FIGS. 12A and 12B are schematic diagrams each for explaining an operation example related to the determination circuit JDGC illustrated in FIG. 11. In FIG. 12A, the counter circuit [symbol] counts the number of clocks of the frequency-divided clock signal CKN1 in, for example, an “H” level period of the frequency-divided clock signal CKN2. In this example, the count value counted by the counter circuit [symbol] is “4”. Note that a frequency division ratio of the frequency divider NDIV2 is set larger than that of the frequency divider NDIV1 as described above. A duration of the “H” level period of the frequency-divided clock signal CKN2 does not depend on the temperature but is constant.

The determination circuit JDGC determines whether or not the count value “4” counted by the counter circuit [symbol] is lower than the predetermined threshold count value, in other words, “3” in this example. That is, the determination circuit JDGC determines whether or not the frequency of the oscillator OSC1 is lower than the predetermined threshold frequency. In this case, since the frequency of the oscillator OSC1 is not lower than the threshold frequency, the determination circuit JDGC outputs an “L” level as the selection signal Ssel.

On the other hand, the sample hold circuit SH samples and holds the reference voltage Vref by using a sampling signal that is synchronized with the frequency-divided clock signal CKN2, and outputs the held reference voltage Vref as a feedback voltage Vfb. The selection circuit SEL selects one of the negative coefficient voltage Vpn2 and the feedback voltage Vfb, based on the selection signal Ssel. In this case, the negative coefficient voltage Vpn2 is selected. Accordingly, the reference voltage Vref having the negative temperature coefficient is generated unless the frequency of the oscillator OSC1 is lower than the threshold frequency.

In FIG. 12B, the count value counted by the counter circuit [symbol] is “2” as different from that illustrated in FIG. 12A. Accordingly, the determination circuit JDGC outputs an “H” level as the selection signal Ssel. The selection circuit SEL selects the feedback voltage Vfb based on the “H” level of the selection signal Ssel.

Accordingly, the feedback voltage Vfb is repeatedly used as the reference voltage Vred unless the frequency of the oscillator OSC1 is not lower than the threshold frequency. In correspondence to the configuration illustrated in FIG. 2, the feedback voltage Vfb is repeatedly used as the reference voltage Vref if the reference voltage Vref reaches the limit voltage Vlmt due to the temperature increase. As a result, the reference voltage Vref is maintained at a constant value. Then, if the frequency of the oscillator OSC1 is made higher than the threshold frequency, in other words, if the reference voltage Vref is made higher than the limit voltage Vlmt by the temperature decrease, the power supply circuit PWGc performs the operation illustrated in FIG. 12A again.

FIG. 13 is a schematic diagram illustrating an operation example of the power supply circuit PWGc illustrated in FIG. 11. As illustrated in FIG. 13, the temperature increase decreases the power supply voltage Vdd2, conclusively decreases the frequency of the clock signal CK1. On the other hand, the frequency of the clock signal CK2 does not depend on the temperature but is constant based on the power supply voltage Vdd3 having no temperature dependence.

The threshold count value in the determination circuit JDGC, in other words, a threshold frequency Fth is set to, for example, a constant frequency lower than the frequency of the clock signal CK2. Note that an upper limit frequency HlmtCK and a lower limit frequency LlmtCK for the frequency of the clock signal are set based on a specification of an operation speed of the logic circuit LGC.

If the frequency of the clock signal CK1 is made lower than the threshold frequency Fth by the temperature increase, the determination circuit JDGC shifts the selection signal Ssel from the “L” level to the “H” level. Correspondingly, the reference voltage generation circuit VRFGc generates the reference voltage Vref based on the feedback voltage Vfb instead of the negative coefficient voltage Vpn2. That is, even in the further increase in the temperature, the reference voltage generation circuit VRFGc maintains the magnitude of the reference voltage Vref to the magnitude provided at the time of the shift of the selection signal Ssel.

The power supply voltage Vdd to be supplied to the logic circuit LGC is generated based on the reference voltage Vref. On the other hand, the power supply voltage Vdd2 to be supplied to the oscillator OSC1 is generated based on the voltage obtained by dividing the reference voltage Vref by using the resistive voltage division circuit RD. As a result, the power supply voltage Vdd2 is lower than the power supply voltage Vdd by a magnitude of a voltage drop VRa of the resistive element Ra. The magnitude of the voltage drop VRa plays a similar role to that of the voltage margin AVm illustrated in FIG. 5.

### Main Effects of Third Embodiment

As described above, the use of the semiconductor device according to the third embodiment provides the similar effects to the various effects described in the first embodiment. Also, since it is determined by the digital circuit whether or not it is necessary to maintain the power supply voltage, the power consumption for the determination may be decreased.

In the foregoing, the invention made by the inventors of the present application has been concretely described based on the embodiments. However, the present invention is not limited to the foregoing embodiments, and various modifications can be made within the scope of the present invention. For example, the above-described embodiments have been explained in detail for the explanation making the present invention understandable, and are not always limited to the one including all structures explained above. Also, a part of the structure of one embodiment can be replaced with the structure of another embodiment, and besides, the structure of another embodiment can be added to the structure of one embodiment. Further, another structure can be added to/eliminated from/replaced with a part of the structure of each embodiment.

What is claimed is:

1. A semiconductor device comprising:
a logic circuit; and
a power supply circuit supplying a power supply voltage to the logic circuit, wherein the logic circuit has characteristics in which a lower limit voltage achieving operations is decreased by temperature increase,
wherein the power supply circuit includes:
a reference voltage generation circuit generating a reference voltage based on a first voltage decreased by temperature increase;
a voltage regulator circuit generating the power supply voltage based on the reference voltage; and
a power supply voltage maintenance circuit suppressing decrease in the reference voltage decreased by temperature increase, before the power supply voltage is made lower than the lower limit voltage by temperature increase.

2. The semiconductor device according to claim 1,
wherein the power supply voltage maintenance circuit suppresses the decrease in the reference voltage decreased by temperature increase, by using a limit voltage having a negative temperature coefficient, and
wherein a gradient of the limit voltage with respect to temperature is gentler than a gradient of the first voltage with respect to temperature.

3. The semiconductor device according to claim 2, wherein the power supply voltage maintenance circuit compares the limit voltage and the first voltage, and determines a magnitude of the reference voltage based on either one of the voltages, whichever is higher.

4. The semiconductor device according to claim 2,
wherein the power supply voltage maintenance circuit includes a limit voltage generation circuit generating the limit voltage, and
wherein the limit voltage generation circuit is made of a transistor having a larger channel length than a channel length of a transistor used for the logic circuit.

5. The semiconductor device according to claim 2,
wherein the power supply voltage maintenance circuit includes a limit voltage generation circuit generating the limit voltage, and
wherein the limit voltage generation circuit includes:
a first transistor formed by the same manufacturing process as a manufacturing process of a p-channel transistor used for the logic circuit to have a diode connection; and
a second transistor connected in series with the first transistor, and formed by the same manufacturing process as a manufacturing process of an n-channel transistor used for the logic circuit to have a diode connection.

6. The semiconductor device according to claim 5,
wherein a channel length of the first transistor is larger than a channel length of the p-channel transistor used for the logic circuit, and
wherein a channel length of the second transistor is larger than a channel length of the n-channel transistor used for the logic circuit.

7. The semiconductor device according to claim 1, further comprising a second power supply voltage maintenance circuit suppressing increase in the reference voltage increased by temperature decrease, before the power supply voltage is made higher than an upper limit voltage of the logic circuit by temperature decrease.

8. The semiconductor device according to claim 7, wherein the second power supply voltage maintenance circuit suppresses the increase in the reference voltage increased by temperature decrease, by using a second voltage having no temperature dependence.

9. The semiconductor device according to claim 8, wherein the second power supply voltage maintenance circuit compares the second voltage and the first voltage, and determines a magnitude of the reference voltage based on either one of the voltages, whichever is lower.

10. The semiconductor device according to claim 1,
wherein the power supply voltage maintenance circuit includes:
a second voltage regulator circuit generating a second power supply voltage being lower than the power supply voltage of the logic circuit and having a negative temperature coefficient; and
a first oscillator oscillating at a frequency corresponding to the second power supply voltage, and
wherein the power supply voltage maintenance circuit determines whether or not it is necessary to suppress the decrease in the reference voltage, based on the frequency of the first oscillator.

11. The semiconductor device according to claim 10,
wherein the power supply voltage maintenance circuit further includes a sample hold circuit sequentially holding the reference voltage output from the reference voltage generation circuit, and
wherein, if it is necessary to suppress the decrease in the reference voltage, the power supply voltage maintenance circuit suppresses the decrease in the reference voltage decreased by temperature increase, by repeatedly using the reference voltage held in the sample hold circuit.

12. The semiconductor device according to claim 10, wherein the power supply voltage maintenance circuit further includes:
a third voltage regulator circuit generating a third power supply voltage based on a second voltage having no temperature dependence;
a second oscillator oscillating at a fixed frequency corresponding to the third power supply voltage;
a frequency detection circuit detecting the frequency of the first oscillator with respect to the fixed frequency of the second oscillator; and
a determination circuit determining whether or not the frequency of the first oscillator detected by the frequency detection circuit is lower than a predetermined threshold frequency.
